(19) United States
(12) Patent Application Publication
(10) Pub. No.: US 2024/0258438 A1
(43) Pub. Date: Aug. 1, 2024

(54) SEMICONDUCTOR DIODE

(71) Applicant: Power IV, Inc., Tokyo (JP)

(72) Inventors: Junji NAKAJIMA, Tokyo (JP); Akimichi DEGAWA, Tokyo (JP); Jun-ichi OKAMURA, Tokyo (JP)

(73) Assignee: Power IV, Inc., Tokyo (JP)

(21) Appl. No.: 18/566,079

(22) PCT Filed: Apr. 22, 2022
(86) PCT No.: PCT/JP2022/018621

§ 371 Date: Nov. 30, 2023

(30) Foreign Application Priority Data
Jun. 1, 2021 (JP) 2021-092625

(51) Int. Cl. H01L 29/861; H01L 29/66

(52) U.S. Cl. CPC H01L 29/8611; H01L 29/66136

(57) ABSTRACT

A semiconductor diode includes: a P-type semiconductor; an N-type semiconductor having a band gap smaller than a band gap of the P-type semiconductor; and an insulator provided between the P-type semiconductor and the N-type semiconductor, the insulator having a band gap larger than the band gap of the P-type semiconductor and the band gap of the N-type semiconductor, a difference between the band gap of the P-type semiconductor and the band gap of the N-type semiconductor is 1 eV or higher, and a difference between the band gap of the P-type semiconductor and the band gap the insulator is 1 eV or lower.

### TECHNICAL FIELD

The present invention relates to a semiconductor diode.

### BACKGROUND ART

A general semiconductor diode includes a P-type semiconductor, an N-type semiconductor, and an insulating layer that is provided between the P-type semiconductor and the N-type semiconductor. The semiconductor diode has rectifying characteristics that allows current to flow only in one direction and is used as a rectifying device.

As disclosed in Japanese Journal of Applied Physics, 2018, Vol. 57, No. 4, p. 041201-1-041201-5, in recent years, attempts have been made to use the semiconductor diode as a charge storage device.

### SUMMARY OF INVENTION

The above-described semiconductor diode includes TiOx as the P-type semiconductor, NiOx as the N-type semiconductor, and SiN as the insulating layer. In the above-described semiconductor diode, carriers are captured at the trapping level in the semiconductor diode when the current flows, and thereby, an electric charge is stored in the semiconductor diode. The semiconductor diode as the charge storage device described above is still in the research stage, and an increase in the charge storage capacity is expected.

An object of the present invention is to increase charge storage capacity of a semiconductor diode.

According to one aspect of the present invention, a semiconductor diode includes: a P-type semiconductor; an N-type semiconductor having a band gap smaller than a band gap of the P-type semiconductor; and an insulator provided between the P-type semiconductor and the N-type semiconductor, the insulator having a band gap larger than the band gap of the P-type semiconductor and the band gap of the N-type semiconductor, a difference between the band gap of the P-type semiconductor and the band gap of the N-type semiconductor is 1 eV or higher, and a difference between the band gap of the P-type semiconductor and the band gap the insulator is 1 eV or lower.

According to another aspect of the present invention, a semiconductor diode includes: a P-type semiconductor; an N-type semiconductor having a band gap larger than a band gap of the P-type semiconductor; an insulator provided between the P-type semiconductor and the N-type semiconductor, the insulator having a band gap larger than the band gap of the P-type semiconductor and the band gap of the N-type semiconductor, a difference between the band gap of the P-type semiconductor and the band gap of the N-type semiconductor is 1 eV or higher, and a difference between the band gap of the N-type semiconductor and the band gap of the insulator is 1 eV or lower.

### BRIEF DESCRIPTION OF DRAWINGS

FIG. 1 is a schematic view of a semiconductor diode according to a first embodiment of the present invention.

FIG. 2 is a diagram showing a band diagram when the semiconductor diode according to the first embodiment of the present invention is open.

FIG. 3 is a diagram showing a band diagram in a state in which forward bias voltage is applied to the semiconductor diode according to the first embodiment of the present invention.

FIG. 4 is a schematic view of the semiconductor diode according to a second embodiment of the present invention.

FIG. 5 is a diagram showing a band diagram when the semiconductor diode according to the second embodiment of the present invention is open.

FIG. 6 is a diagram showing a band diagram in a state in which the forward bias voltage is applied to the semiconductor diode according to the second embodiment of the present invention.

FIG. 7 is a diagram showing a band diagram when the semiconductor diode in a comparative example is open.

FIG. 8 is a diagram showing a band diagram in a state in which the forward bias voltage is applied to the semiconductor diode in the comparative example.

### DESCRIPTION OF EMBODIMENTS

### First Embodiment

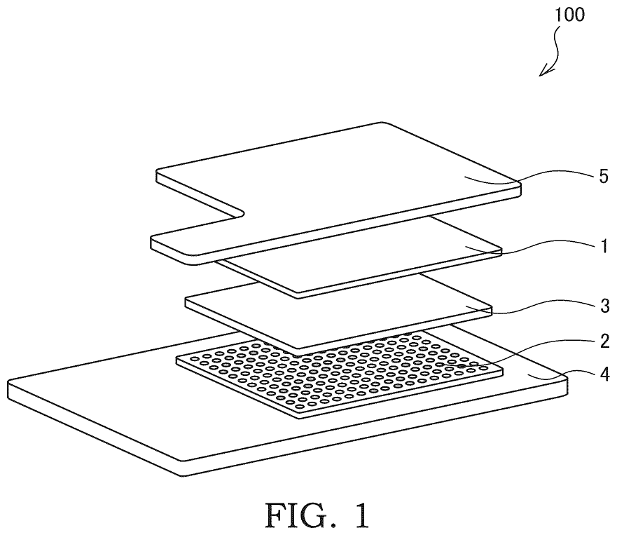

A semiconductor diode 100 according to a first embodiment of the present invention will be described with reference to FIGS. 1 to 3. The semiconductor diode 100 is used a charge storage device that stores and releases the electric charge.

As shown in FIG. 1, the semiconductor diode 100 is provided with a P-type semiconductor 1, an N-type semiconductor 2, an insulator 3 that is provided between the P-type semiconductor 1 and the N-type semiconductor 2, a first electrode 4 that is electrically connected to the N-type semiconductor 2, and a second electrode 5 that is electrically connected to the P-type semiconductor 1. The semiconductor diode 100 is formed by stacking the first electrode 4, the N-type semiconductor 2, the insulator 3, the P-type semiconductor 1, and the second electrode 5 in this order.

The oxide semiconductor having a wide band gap such as NiO is used for the P-type semiconductor 1, a single-element semiconductor such as an N-type silicon (n-Si) is used for the N-type semiconductor 2, and a perovskite compound such as LiNbO₃ is used for the insulator 3. A surface of the N-type semiconductor 2 facing the insulator 3 is formed to have a shape with projections and depressions. The first electrode 4 is a metal thin film made of stainless steel, etc. and has functions of a substrate and an electrode. The second electrode 5 is the metal thin film made of Al, Cu, or the like.

Next, a method of forming the semiconductor diode 100 will be described.

The N-type semiconductor 2 is first formed on the first electrode 4 by the CVD or the sputtering. Thus-formed N-type semiconductor 2 is selectively anisotropically etched by lithography or imprinting to form the projections and depressions on the surface. Next, the insulator 3 is deposited by the CVD, the sputtering, or the EB vapor deposition on the N-type semiconductor 2 on which the projections and depressions are formed, and the P-type semiconductor 1 is deposited by the CVD, the sputtering, or the EB vapor deposition on the insulator 3 in a similar manner. Subsequently, the second electrode 5 is formed by using the metal thin film made of Al, Cu, or the like. As a result, the PIN diode structure of the semiconductor diode 100 is formed.

Note that, for the method of forming the semiconductor diode 100, in addition to the dry methods utilizing vacuum equipment such as the CVD, the sputtering, and the EB vapor deposition, the semiconductor diode 100 may also be formed by providing powders for each of the N-type semiconductor 2, the P-type semiconductor 1, and the insulator 3, stacking them in order to form layers, and compressing them. In addition, a method in which the semiconductor diode 100 is formed by forming layers by compressing the powders for each of the layers and compressing the layers that are stacked, a method in which the semiconductor diode 100 is formed by adding a binder material to the powders for each of the N-type semiconductor 2, the P-type semiconductor 1, and the insulator 3 and stacking them using a coating method, and so forth may also be possible.

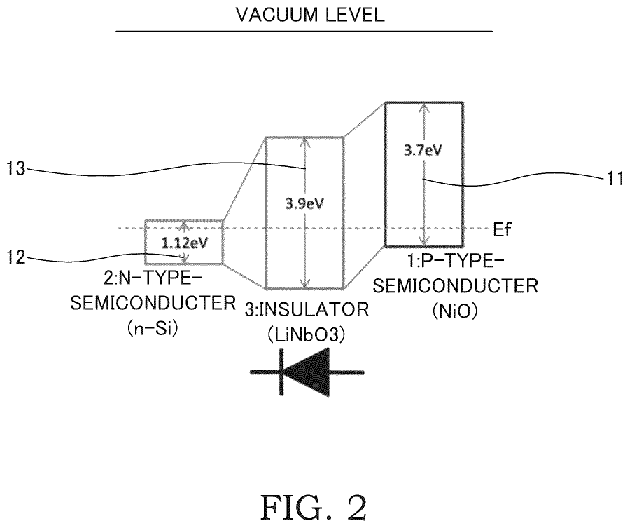

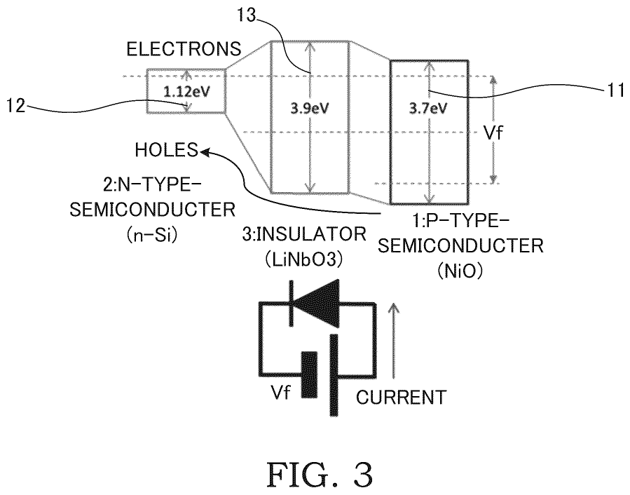

Next, operation of the semiconductor diode 100 will be described with reference to FIGS. 2 and 3. FIG. 2 is a diagram showing a band diagram when the semiconductor diode 100 is open, FIG. 3 is a diagram showing a band diagram in a state in which the forward bias voltage is applied to the semiconductor diode 100 from outside. In other words, FIG. 2 is the diagram showing the band diagram in a state in which the P-type semiconductor 1 and the N-type semiconductor 2 are joined (PN junction), and FIG. 3 is the diagram showing the band diagram when positive voltage is applied to the P-type semiconductor 1 by using the N-type semiconductor 2 as the reference from the outside the semiconductor diode 100. FIGS. 2 and 3 show a band gap 11 of the P-type semiconductor 1 (NiO), a band gap 12 of the N-type semiconductor 2 (n-Si), and a band gap 13 of the insulator 3 (LiNbO₃), and the Fermi level Ef (see FIG. 2) and the energy-level Vf of the forward bias voltage (see FIG. 3) are also shown. The upper end of each band gap represents a conduction band, and the lower end thereof represents the energy-level of a valence band. The energy-level of each material is measured by observing photoelectrons and thermoelectrons.

The band gap 11 of the P-type semiconductor 1 (NiO) is large and is specifically 3.7 eV. The band gap 12 of the N-type semiconductor 2 (n-Si) is small and is specifically 1.12 eV. As described above, the difference between the band gaps 11 and 12 of the P-type semiconductor 1 and the N-type semiconductor 2 is 1 eV or higher. In addition, the band gap 13 of the insulator 3 (LiNbO₃) is 3.9 eV. The band gap of the insulator 3 is closer to that of the P-type semiconductor 1, and the difference between the band gaps 13 and 11 of the insulator 3 and the P-type semiconductor 1 is 1 eV or lower. As described above, the band gap of the insulator 3 is larger than those of the P-type semiconductor 1 and the N-type semiconductor 2.

When the P-type semiconductor 1 and the N-type semiconductor 2 are joined to form the PN junction, a depletion layer (or electrical double layer) is formed at the junction interface. An electric field is generated in the depletion layer, and as shown in FIG. 2, a potential difference (built-in potential) is generated between both ends of the depletion layer, in other words, between the P-type semiconductor 1 and the N-type semiconductor 2. In this state, migration of electrons and holes between the P-type semiconductor 1 and the N-type semiconductor 2 are not caused due to the electric field in the depletion layer.

In this state, as shown in FIG. 3, when the forward bias voltage is applied to the PN junction from the outside, in other words, when the positive voltage is applied to the P-type semiconductor 1 from the outside, the electric field in the depletion layer generated at the PN junction is weakened by the electric field that is generated by the external voltage. As a result, the energy-level of the valence band of the P-type semiconductor 1 becomes lower than the energy-level of the valence band of the N-type semiconductor 2, and thereby, the energy barrier for migration of the holes in the P-type semiconductor 1 to the N-type semiconductor 2 is lowered. Thus, as shown by arrows in FIG. 3, the holes migrate from the P-type semiconductor 1 to the N-type semiconductor 2.

On the other hand, as shown in FIG. 3, in a state in which the forward bias voltage is applied to the PN junction from the outside, the energy-level of the conduction band of the N-type semiconductor 2 is lower than the energy-level of the conduction band of the P-type semiconductor 1. In other words, the energy of the conduction band of the N-type semiconductor 2 is lower than the energy of the conduction band of the P-type semiconductor 1 (negative). Thus, the energy barrier for migration of the electrons in the N-type semiconductor 2 to the P-type semiconductor 1 is high, and the migration of the electrons from the N-type semiconductor 2 to the P-type semiconductor 1 is blocked because the energy barrier cannot be overcome. As described above, in the semiconductor diode 100, the forward current (drift current) flows as the holes migrate from the P-type semiconductor 1 to the N-type semiconductor 2 via the insulator 3.

In the semiconductor diode 100, the band gap of the P-type semiconductor 1 differs from the band gap of the N-type semiconductor 2 (specifically, the difference is 1 eV or higher). Therefore, as described above, when the forward bias voltage is applied, it is possible to achieve a state in which the energy-level of the valence band of the P-type semiconductor 1 is lower than the energy-level of the valence band of the N-type semiconductor 2 and the energy-level of the conduction band of the N-type semiconductor 2 is lower than the energy-level of the conduction band of the P-type semiconductor 1.

In the above, description has been given on the basis of the energy-level, in other words, the magnitude of the energy. If the description is given on the basis of the energy level using the vacuum level of the N-type semiconductor on the ground side as a reference, in the semiconductor diode 100, in a state in which the forward current is flowing, the energy level of the conduction band of the N-type semiconductor 2 is higher than the energy level of the conduction band of the P-type semiconductor 1, and the energy level of the valence band of the P-type semiconductor 1 is higher than the energy level of the valence band of the N-type semiconductor 2. In other words, in a state in which the forward current is flowing, the P-type semiconductor 1 and the N-type semiconductor 2 are set such that the energy level of the conduction band of the N-type semiconductor 2 becomes higher than the energy level of the conduction band of the P-type semiconductor 1 and such that the energy level of the valence band of the P-type semiconductor 1 becomes higher than the energy level of the valence band of the N-type semiconductor 2.

In the semiconductor diode 100, when the forward current flows as described above, some of the holes are trapped at the trapping levels (accumulation layers) generated in the insulator 3 and generated at interfaces between the insulator 3 and each of the P-type semiconductor 1 and the N-type semiconductor 2. As a result, the electric charge is accumulated in the semiconductor diode 100 serving as the charge storage device, and the semiconductor diode 100 is charged. When the application of the forward bias voltage is stopped and an external load is connected to the semiconductor diode 100, the holes accumulated at the trapping levels are released to the outside, and thus, the semiconductor diode 100 is discharged.

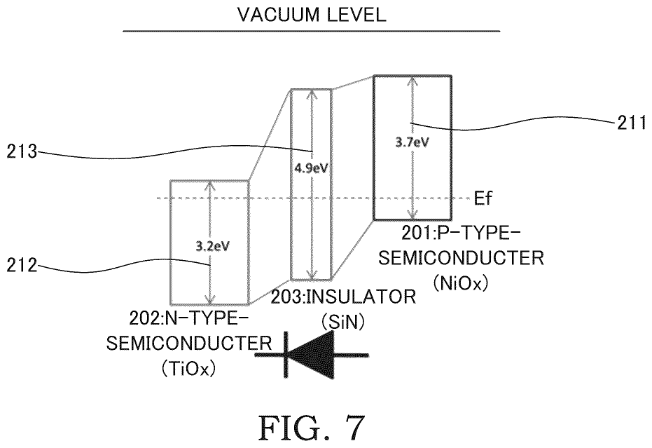

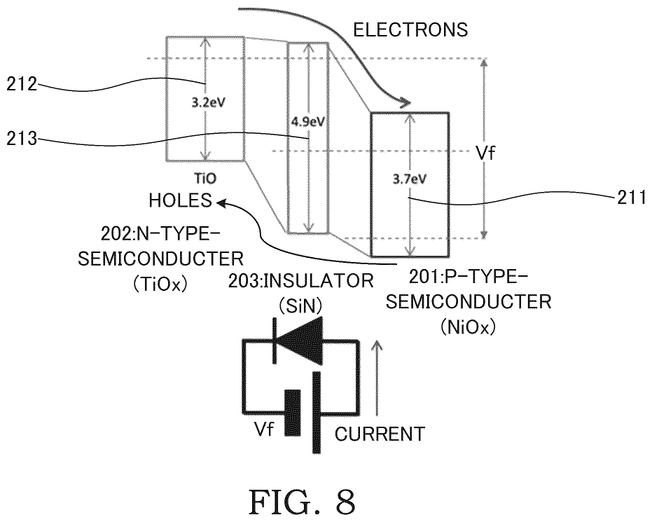

As a comparative example, a semiconductor diode 300 described in Japanese Journal of Applied Physics, 2018, Vol. 57, No. 4, p. 041201-1-041201-5 will be described with reference to FIGS. 7 and 8.

The semiconductor diode 300 is provided with a P-type semiconductor 201, an N-type semiconductor 202, and an insulator 203 that is provided between the P-type semiconductor 201 and the N-type semiconductor 202. The overall configuration of the semiconductor diode 300 is similar to that of the semiconductor diode 100, and therefore, the illustration thereof will be omitted. As shown in FIG. 7, NiOx is used for the P-type semiconductor 201, and a band gap 211 is 3.7 eV. TiOx is used for the N-type semiconductor 202, and a band gap 212 is 3.2 eV. As described above, the band gap of the P-type semiconductor 201 is close to the band gap of the N-type semiconductor 202, and the difference between the band gaps 211 and 212 of the P-type semiconductor 201 and the N-type semiconductor 202 is smaller than 1 eV. In addition, SiN is used for the insulator 203, and a band gap 213 is 4.9 eV.

Operation of the semiconductor diode 300 will be described with reference to FIGS. 7 and 8. FIG. 7 is a diagram showing a band diagram when the semiconductor diode 300 is open, and FIG. 8 is a diagram showing a band diagram in a state in which the forward bias voltage is applied to the semiconductor diode 300 from the outside. FIGS. 7 and 8 show the band gap 211 of the P-type semiconductor 201 (NiOx), the band gap 212 of the N-type semiconductor 202 (TiOx), and the band gap 213 of the insulator 203 (SiN), and the Fermi level Ef (see FIG. 7) and the energy-level Vf of the forward bias voltage (see FIG. 8) are also shown.

In a state in which the P-type semiconductor 201 and the N-type semiconductor 202 are joined to form the PN junction as shown in FIG. 7, as shown in FIG. 8, the forward bias voltage is applied to the PN junction from the outside. Then, the energy-level of the valence band of the P-type semiconductor 201 becomes lower than the energy-level of the valence band of the N-type semiconductor 202, and the holes migrate from the P-type semiconductor 201 to the N-type semiconductor 202. In addition, the energy-level of the conduction band of the N-type semiconductor 202 becomes higher than the energy-level of the conduction band of the P-type semiconductor 201, and the electrons migrate from the N-type semiconductor 202 to the P-type semiconductor 201. As described above, in the semiconductor diode 300, the forward current flows as both of the electrons and holes migrate between the P-type semiconductor 201 and the N-type semiconductor 202.

In the semiconductor diode 300, the band gap of the P-type semiconductor 201 is close to the band gap of the N-type semiconductor 202 (specifically, the difference is 0.5 eV). Therefore, as in the semiconductor diode 100, when the forward bias voltage is applied, it is difficult to achieve a state in which the energy-level of the valence band of the P-type semiconductor 201 is lower than the energy-level of the valence band of the N-type semiconductor 202, and the energy-level of the conduction band of the N-type semiconductor 202 is lower than the energy-level of the conduction band of the P-type semiconductor 201.

In the semiconductor diode 300, as described above, when the forward current flows, some of the electrons and the holes are trapped at the trapping levels generated in the insulator 203 and generated at interfaces between the insulator 203 and each of the P-type semiconductor 201 and the N-type semiconductor 202. As a result, the electric charge is accumulated in the semiconductor diode 300. The trapping level is formed, for example, by introducing silicon compound particles into an N-type oxide semiconductor and a P-type oxide semiconductor.

As described above, in the semiconductor diode 300 in the comparative example, because the band gap of the P-type semiconductor 201 is close to the band gap of the N-type semiconductor 202, the forward current flows by the migration of both of the electrons and the holes. Thus, the electrons and the holes that migrate as the forward current are recombined and disappear before they are trapped at the trapping levels, and it is considered that the electrons and the holes cannot be trapped and accumulated at the trapping levels efficiently.

In contrast, in the semiconductor diode 100 according to the first embodiment, because the band gap of the P-type semiconductor 1 and the band gap of the N-type semiconductor 2 are different, it is possible to achieve a state in which the holes are migrated and the forward current flows as described above, and the holes are trapped at the trapping levels generated in the insulator 3 and generated at the interfaces between the insulator 3 and each of the P-type semiconductor 1 and the N-type semiconductor 2. As a result, the recombination of the moving holes with the electrons is prevented, and thus, the holes are prevented from recombining with the electrons and disappearing before they are trapped at the trapping levels. Thus, the holes can be trapped and accumulated efficiently at the trapping levels, and so, it is possible to increase a charge storage capacity of the semiconductor diode 100. As described above, with the semiconductor diode 100, it is possible to increase the charge storage capacity without compromising its thin shape, which is a feature of the charge storage device.

Note that if the forward bias voltage is further increased from the state shown in FIG. 3, the energy-level of the conduction band of the N-type semiconductor 2 becomes higher than the energy-levels of the conduction bands of the insulator 3 and the P-type semiconductor 1. Thus, the electrons begin to migrate from N-type semiconductor 2 to the P-type semiconductor 1. In this state, the forward current cannot be limited to that due to the migration of the holes, and so, it becomes more difficult to accumulate the electric charge in the semiconductor diode 100 compared with the state in which the forward current flows due to the migration of the holes. In other words, in the semiconductor diode 100, there is an upper limit for the forward bias voltage that can be applied. The upper limit of the forward bias voltage is the maximum voltage at which the energy-level of the conduction band of the N-type semiconductor 2 becomes lower than the higher of the energy-level of the conduction band of the insulator 3 or the P-type semiconductor 1.

In the semiconductor diode 100, the larger the band gaps 11 and 13 of the P-type semiconductor 1 and the insulator 3 and the smaller the band gap 12 of the N-type semiconductor 2, the higher the upper limit of the forward bias voltage from the outside at which the forward current flows due to the migration of the holes. The accumulation of the electric charge to the semiconductor diode 100 is terminated when an amount of the electric charge sufficient to reduce the forward bias voltage from the outside is trapped at the trapping level. Thus, by further increasing the forward bias voltage from the outside while maintaining the state in which the forward current flows to the semiconductor diode 100 due to the migration of the holes, it is possible to further increase the amount of accumulated electric charge in the semiconductor diode 100.

In the semiconductor diode 100, in the state in which the forward current flows due to the migration of the holes, it is preferable that the positive voltage applied from the outside be 1 V or higher. In other words, it is preferable that the band gaps 11 and 13 of the P-type semiconductor 1 and the insulator 3 be higher than the band gap 12 of the N-type semiconductor 2 by 1 eV or higher, and it is preferable that the difference between the band gaps 11 and 13 of the P-type semiconductor 1 and the insulator 3 is 1 eV or lower. By forming the semiconductor diode 100 as described above, it is possible to increase the upper limit of the forward bias voltage from the outside, at which the state in which the forward current flows due to the migration of the holes is achieved, to 1 V or higher. Because a power supply voltage for commonly used semiconductor electronic devices ranges from 1 to 5 V, if the forward bias voltage from the outside at the state in which the forward current flows due to the migration of the holes is 1 V or higher, it is possible to sufficiently operate the semiconductor electronic devices by the semiconductor diode 100. However, in the semiconductor diode 100, at the state in which the forward current flows due to the migration of the holes, the positive voltage applied from the outside may be lower than 1 V. Whether the voltage accumulated in the semiconductor diode 100 is low or high, by connecting a plurality of the semiconductor diodes 100 in series, it is possible to ensure a large voltage.

In addition, in the semiconductor diode 100, the surface of the N-type semiconductor 2 facing the insulator 3 is formed to have the shape with projections and depressions. By increasing the surface area of the interface between the N-type semiconductor 2 and the insulator 3 as described above, it is possible to increase the charge storage capacity of the trapping level to further increase the amount of the accumulated electric charge of the semiconductor diode 100. Note that, the surface area of the interface between the N-type semiconductor 2 and the insulator 3 may also be increased by subjecting the surface of the N-type semiconductor 2 facing the insulator 3 to anodization to make it porous (porous silicon). In addition, the surface of the N-type semiconductor 2 facing the insulator 3 may also be subjected to a surface modification at the atomic level by means of ion beam implantation, ion milling, plasma irradiation, or the like. In addition, the surface of the N-type semiconductor 2 facing the insulator 3 may not be formed to have the shape with projections and depressions and the porous shape.

In the first embodiment, in the semiconductor diode 100, the oxide semiconductor having a wide band gap such as NiO, etc. is used for the P-type semiconductor 1. In addition, the single-element semiconductor such as n-Si is used for the N-type semiconductor 2, and the perovskite compound such as LiNbO₃, etc. is used for the insulator 3. However, the configurations of the P-type semiconductor 1, the N-type semiconductor 2, and the insulator 3 are not limited thereto, and for example, the oxide semiconductor having relatively large band gap, such as Cr₂O₃, etc. may also be used as the P-type semiconductor 1. In the semiconductor diode 100, in a state in which the forward current is flowing, it suffices that the energy level of the conduction band of the N-type semiconductor 2 is higher than the energy level of the conduction band of the P-type semiconductor 1, and the energy level of the valence band of the P-type semiconductor 1 is higher than the energy level of the valence band of the N-type semiconductor 2. With such a configuration, the holes are prevented from recombining with the electrons and disappearing before they are trapped at the trapping levels, and it is possible to increase the charge storage capacity of the semiconductor diode 100.

According to the first embodiment described above, following operational advantages are afforded.

In the semiconductor diode 100, because the band gap of the P-type semiconductor 1 and the band gap of the N-type semiconductor 2 are different, it is possible to achieve a state in which the forward current flows due to the migration of the holes. As a result, the holes are trapped at the trapping levels generated in the insulator 3 and generated at the interfaces between the insulator 3 and each of the P-type semiconductor 1 and the N-type semiconductor 2. Therefore, the holes are prevented from recombining with the electrons and disappearing before they are trapped at the trapping levels. Thus, the holes can be trapped and accumulated efficiently at the trapping level, and so, it is possible to increase the charge storage capacity of the semiconductor diode 100 without compromising its thin shape.

With the semiconductor diode 100, in the state in which the forward current flows due to the migration of the holes, the semiconductor electronic devices can be sufficiently operated by the semiconductor diode 100 given that the positive voltage applied from the outside is 1 V or higher. In the semiconductor diode 100, even if the positive voltage applied from the outside is lower than 1 V at the state in which the forward current flows due to the migration of the holes, by connecting a plurality of the semiconductor diodes 100 in series, it is possible to ensure a large voltage.

### Second Embodiment

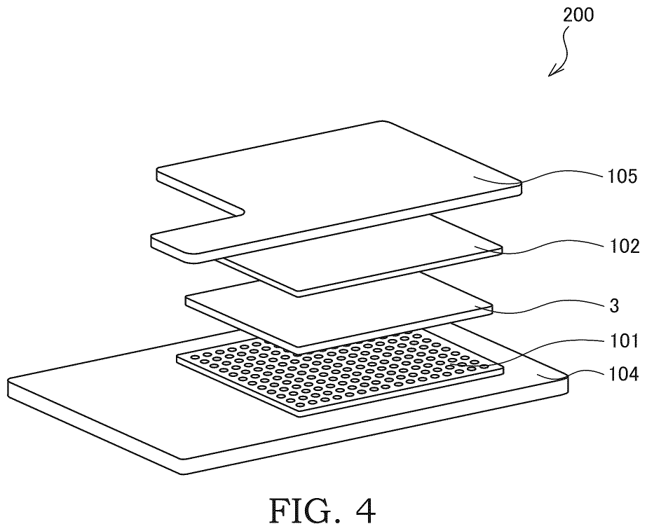

Next, a semiconductor diode 200 according to a second embodiment of the present invention will be described with reference to FIGS. 4 to 6. In the following, differences from the above-described first embodiment will be mainly described.

As shown in FIG. 4, the semiconductor diode 200 is provided with a P-type semiconductor 101, an N-type semiconductor 102, the insulator 3 that is provided between the P-type semiconductor 101 and the N-type semiconductor 102, a first electrode 104 that is electrically connected to the P-type semiconductor 101, and a second electrode 105 that is electrically connected to the N-type semiconductor 102.

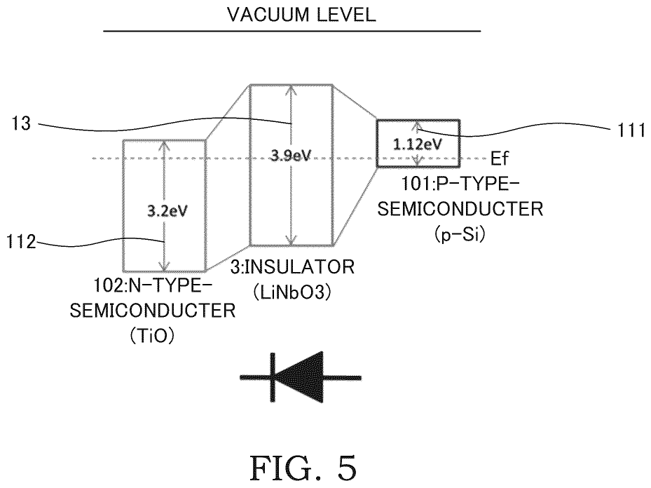

In the above-described first embodiment, in the semiconductor diode 100, NiO is used for the P-type semiconductor 1, n-Si, etc. is used for the N-type semiconductor 2, the band gaps 11 and 13 of the P-type semiconductor 1 and the insulator 3 are large, and the band gap 12 of the N-type semiconductor 2 is small. In contrast, in the second embodiment, as shown in FIG. 5, in the semiconductor diode 200, the single-element semiconductor such as P-type silicon (p-Si) is used for the P-type semiconductor 101, the oxide semiconductor such as TiO, etc. is used for the N-type semiconductor 102, the band gaps 112 and 13 of the N-type semiconductor 102 and the insulator 3 are large, and a band gap 111 of the P-type semiconductor 101 is small.

The semiconductor diode 200 is formed by stacking the first electrode 104, the P-type semiconductor 101, the insulator 3, the N-type semiconductor 102, and the second electrode 105 in this order. The P-type semiconductor 101 is first formed on the first electrode 104 by the CVD or the sputtering. Thus-formed P-type semiconductor 101 is subjected to lithography or imprinting to form the projections and depressions on the surface. Next, the insulator 3 is deposited by the CVD, the sputtering, or the EB vapor deposition on the P-type semiconductor 101 on which the projections and depressions are formed, and the N-type semiconductor 102 is deposited by the CVD, the sputtering, or the EB vapor deposition on the insulator 3 in a similar manner. Subsequently, the second electrode 105 is formed by using the metal thin film made of Al, Cu, or the like. As a result, the PIN diode structure of the semiconductor diode 200 is formed.

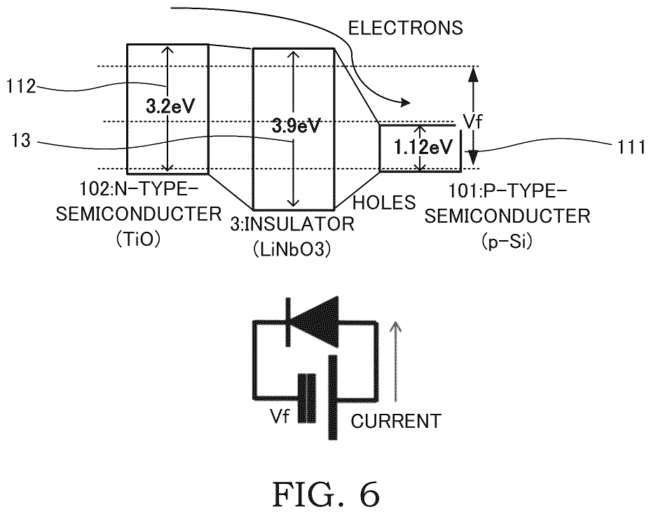

FIG. 5 is a diagram showing a band diagram when the semiconductor diode 200 is open, and FIG. 6 is a diagram showing a band diagram in a state in which the forward bias voltage is applied to the semiconductor diode 200 from the outside. FIGS. 5 and 6 show the band gap 111 of the P-type semiconductor 101 (p-Si), the band gap 112 of the N-type semiconductor 102 (TiO), and the band gap 13 of the insulator 3 (LiNbO₃), and the Fermi level Ef (see FIG. 5) and the energy-level Vf of the forward bias voltage (see FIG. 6) are also shown.

The band gap 111 of the P-type semiconductor 101 (p-Si) is 1.12 eV, and the band gap 112 of the N-type semiconductor 102 (TiO) is 3.2 eV. As described above, the difference between the band gaps 111 and 112 of the P-type semiconductor 101 and the N-type semiconductor 102 is 1 eV or higher. In addition, the band gap 13 of the insulator 3 (LiNbO₃) is 3.9 eV, and the difference between the band gaps 112 and 13 of the N-type semiconductor 102 and the insulator 3 is 1 eV or lower. As described above, the band gap of the insulator 3 is larger than the band gaps of the P-type semiconductor 101 and the N-type semiconductor 102.

In a state in which the P-type semiconductor 101 and the N-type semiconductor 102 are joined to form the PN junction as shown in FIG. 5, the forward bias voltage is applied to the PN junction from the outside as shown in FIG. 6. Then, the energy-level of the conduction band of the N-type semiconductor 102 becomes higher than the energy-level of the conduction band of the P-type semiconductor 101, and as shown by arrows in FIG. 6, the electrons migrate from the N-type semiconductor 102 to the P-type semiconductor 101. On the other hand, the energy-level of the valence band of the P-type semiconductor 101 is higher than the energy-level of the valence band of the N-type semiconductor 102. Thus, the energy barrier for the migration of the holes in the P-type semiconductor 101 to the N-type semiconductor 102 via the insulator 3 is high, and so, the migration of the holes from the P-type semiconductor 101 to the N-type semiconductor 102 is blocked because the energy barrier cannot be overcome. As described above, in the semiconductor diode 200, the forward current flows due to the migration of the electrons.

In the semiconductor diode 200, the band gap of the P-type semiconductor 101 differs from the band gap of the N-type semiconductor 102 (specifically, the difference is 1 eV or higher). Therefore, as described above, when the forward bias voltage is applied, it is possible to achieve a state in which the energy-level of the conduction band of the N-type semiconductor 102 is higher than the energy-level of the conduction band of the P-type semiconductor 101 and the energy-level of the valence band of the P-type semiconductor 101 is higher than the energy-level of the valence band of the N-type semiconductor 102.

In other words, in the semiconductor diode 200, in a state in which the forward current is flowing, the energy level of the valence band of the P-type semiconductor 101 is lower than the energy level of the valence band of the N-type semiconductor 102, and the energy level of the conduction band of the N-type semiconductor 102 is lower than the energy level of the conduction band of the P-type semiconductor 101. In other words, in a state in which the forward current is flowing, the P-type semiconductor 101 and the N-type semiconductor 102 are set such that the energy level of the valence band of the P-type semiconductor 101 becomes lower than the energy level of the valence band of the N-type semiconductor 102 and such that the energy level of the conduction band of the N-type semiconductor 102 becomes lower than the energy level of the conduction band of the P-type semiconductor 101.

As described above, in the semiconductor diode 200, because the band gap of the P-type semiconductor 101 and the band gap of the N-type semiconductor 102 are different, the forward current flows due to the migration of the electrons. Thus, the electrons are trapped at the trapping levels generated in the insulator 3 and generated at interfaces between the insulator 3 and each of the P-type semiconductor 101 and the N-type semiconductor 102. Therefore, similarly to the semiconductor diode 100, the electrons are prevented from recombining with the holes and disappearing before they are trapped at the trapping levels, and so, it is possible to cause the electrons to be trapped and accumulated efficiently at the trapping level. Thus, it is possible to increase the charge storage capacity of the semiconductor diode 200.

Note that if the forward bias voltage is further increased from the state shown in FIG. 6, the energy-level of the valence band of the N-type semiconductor 102 becomes higher than the energy-level of the valence bands of the insulator 3 and the P-type semiconductor 101. Thus, the holes begin to migrate from the N-type semiconductor 102 to the P-type semiconductor 101. In this state, the forward current cannot be limited to that due to the migration of the electrons, and so, it becomes more difficult to accumulate the electric charge in the semiconductor diode 200 compared with the state in which the forward current flows due to the migration of the electrons. In other words, in the semiconductor diode 200, there is the upper limit for the forward bias voltage that can be applied. The upper limit of the forward bias voltage is the maximum voltage at which the energy-level of the valence band of the P-type semiconductor 101 becomes higher than the lower of the energy-level of the valence band of the N-type semiconductor 102 or the insulator 3.

In the semiconductor diode 200, similarly to the semiconductor diode 100, in the state in which the forward current flows due to the migration of the electrons, it is preferable that the positive voltage applied from the outside be 1 V or higher. In other words, it is preferable that the band gaps 112 and 13 of the N-type semiconductor 102 and the insulator 3 be higher than the band gap 111 of the P-type semiconductor 101 by 1 eV or higher, and it is preferable that the difference between the band gaps 112 and 13 of the N-type semiconductor 102 and the insulator 3 be 1 eV or lower. By forming the semiconductor diode 200 as described above, it is possible to increase the upper limit of the forward bias voltage from the outside, at which the state in which the forward current flows due to the migration of the electrons is achieved, to 1 V or higher, and so, it is possible to cause the semiconductor electronic devices to be sufficiently operated by the semiconductor diode 200. However, in the semiconductor diode 200, similarly to the semiconductor diode 100, at the state in which the forward current flows due to the migration of the electrons, the positive voltage applied from the outside may be lower than 1 V.

In addition, in the semiconductor diode 200, the surface of the P-type semiconductor 101 facing the insulator 3 is formed to have the shape with projections and depressions. By increasing the surface area of the interface between the P-type semiconductor 101 and the insulator 3 as described above, similarly to the semiconductor diode 100, it is possible to increase the charge storage capacity of the trapping level to further increase the amount of the accumulated electric charge of the semiconductor diode 200. Note that, the surface area of the interface between the P-type semiconductor 101 and the insulator 3 may also be increased by subjecting the surface of the P-type semiconductor 101 facing the insulator 3 to anodization to make it porous (porous silicon). In addition, the surface of the P-type semiconductor 101 facing the insulator 3 may also be subjected to a surface modification at the atomic level by means of ion beam implantation, ion milling, plasma irradiation, or the like. In addition, the surface of the P-type semiconductor 101 facing the insulator 3 may not be formed to have the shape with projections and depressions and the porous shape.

In the second embodiment, in the semiconductor diode 200, p-Si is used for the P-type semiconductor 101, TiO is used for the N-type semiconductor 102, and LiNbO₃ is used for the insulator 3. However, the configurations of the P-type semiconductor 101, the N-type semiconductor 102, and the insulator 3 are not limited thereto, and for example, the oxide semiconductor having relatively large band gap, such as Ta₂O₅, WO₃, and so forth may also be used as the N-type semiconductor 102. In the semiconductor diode 200, in a state in which the forward current is flowing, it suffices that the energy level of the valence band of the P-type semiconductor 101 is lower than the energy level of the valence band of the N-type semiconductor 102, and the energy level of the conduction band of the N-type semiconductor 102 is lower than the energy level of the conduction band of the P-type semiconductor 101. With this configuration, the electrons are prevented from recombining with the holes and disappearing before they are trapped at the trapping levels, and so, it is possible to increase the charge storage capacity of the semiconductor diode 200.

Following modifications are also within the scope of the present invention, and it is also possible to combine the configurations shown in the modifications with the configurations described in the above-mentioned embodiments, to combine the configurations described in the different embodiments described above with each other, and to combine the configurations described in the different modifications described below with each other.

### First Modification

In the above-mentioned embodiment, in the semiconductor diode 100, 200, LiNbO₃, etc. is used for the insulator 3. However, a compound having a perovskite structure and piezoelectric characteristics, such as a lithium-based perovskite compound such as Li₃PS₄, LiBH₄, or the like, a manganese-based perovskite compound such as LaMnO₃, etc., and so forth, may also be used as the insulator 3. In this configuration, as a physical pressure is applied to the P-type semiconductor 1 and the N-type semiconductor 2 by an internal electric field that is generated when the electric charge is accumulated in the semiconductor diode 100, 200, mobilities of the electrons and the holes are increased to increase the speed at which the electrons and the holes are trapped at the trapping level. Thus, it is possible to further increase the amount of the accumulated electric charge of the semiconductor diode 100, 200.

### Second Modification

In the above-mentioned embodiment, the semiconductor diode 100, 200 is provided with the P-type semiconductor 1, 101, the N-type semiconductor 2, 102, and the insulator 3. In addition to or instead of this configuration, a zero band-gap semiconductor material such as a graphene layer, etc. may also be provided in the semiconductor diode 100, 200. In this case, the graphene layer is provided between the N-type semiconductor 2 and the insulator 3 or may serve as a replacement for the N-type semiconductor, and the graphene layer is provided between the P-type semiconductor 101 and the insulator 3 or may serve as a replacement for the P-type semiconductor. In other words, the graphene layer is provided between the insulator 3 and the one with the smaller band gap among the P-type semiconductor 1, 101 and the N-type semiconductor 2, 102, or the graphene layer is replaced with the semiconductor with the smaller band gap. In addition, the graphene layer can also replace the N-type semiconductor by forming a graphene doped with phosphorus (P) on the N-type semiconductor 2 or directly on the substrate electrode by using, for example, a CVD or a liquid phase growth. In this configuration, it is possible to further increase the forward bias voltage from the outside in a state in which the forward current flows due to the migrations of the electrons and the holes and to further increase the amount of the accumulated electric charge of the semiconductor diode 100, 200.

### Third Modification

In the above-mentioned embodiment, the semiconductor diodes 100 and 200 are used as the charge storage device that stores and releases the electric charge. The charge storage device is, for example, either a device that supplies the electric charge to other semiconductor devices, etc., which are provided on the substrate, or a secondary battery that supplies the electric charge to other electronic devices, etc.

As described above, when the semiconductor diode serving as the charge storage device is formed, the combination is employed such that the difference between the semiconductor having a wide band gap and the semiconductor having a small band gap is 1 eV or higher, and the semiconductor diode has: the PIN diode structure including the P-type semiconductor having the wide band gap, the insulating layer having the band gap relatively close to the band gap of the semiconductor, and the N-type semiconductor having the small band gap; or the PIN diode structure including the N-type semiconductor having the wide band gap, the insulating layer having the band gap relatively close to the band gap of the semiconductor, and the P-type semiconductor having the small band gap. The surface of the semiconductor having the small band gap is processed so as to have the shape with projections and depressions or the porous shape in order to increase the surface area of the interface between the insulating layer of the PIN diode and the semiconductor having the small band gap of the PIN diode. A current component flowing through the PIN diode when the charge storage device is charged by using the semiconductor diode is controlled such that either one of the drift current of the holes or the drift current of the electrons becomes a main current component to reduce a probability of recombination of the drift current of the electrons and the drift current of the holes in the PIN diode. Thereby, it becomes possible to efficiently accumulate the electric charge by the holes or the electric charge by the electrons to the trapping level in the PIN diode.

Embodiments of the present invention were described above, but the above embodiments are merely examples of applications of the present invention, and the technical scope of the present invention is not limited to the specific constitutions of the above embodiments.

With respect to the above description, the contents of application No. 2021-092625, with a filing date of Jun. 1, 2021 in Japan, are incorporated herein by reference.

1. A semiconductor diode comprising:
a P-type semiconductor;
an N-type semiconductor having a band gap smaller than a band gap of the P-type semiconductor; and
an insulator provided between the P-type semiconductor and the N-type semiconductor, the insulator having a band gap larger than the band gap of the P-type semiconductor and the band gap of the N-type semiconductor, wherein
a difference between the band gap of the P-type semiconductor and the band gap of the N-type semiconductor is 1 eV or higher, and
a difference between the band gap of the P-type semiconductor and the band gap the insulator is 1 eV or lower.

2. The semiconductor diode according to claim 1, wherein
in a state in which positive voltage is applied to the P-type semiconductor from outside of the semiconductor diode by using the N-type semiconductor as a reference,
an energy level of a conduction band of the N-type semiconductor is set so as to be higher than an energy level of a conduction band of the P-type semiconductor, and
an energy level of a valence band of the P-type semiconductor is set so as to be higher than an energy level of a valence band of the N-type semiconductor.

3. The semiconductor diode according to claim 1, wherein
an oxide semiconductor is used for the P-type semiconductor, and
an N-type single-element semiconductor or an N-type zero band-gap semiconductor is used for the N-type semiconductor.

4. A semiconductor diode comprising:
a P-type semiconductor;
an N-type semiconductor having a band gap larger than a band gap of the P-type semiconductor;
an insulator provided between the P-type semiconductor and the N-type semiconductor, the insulator having a band gap larger than the band gap of the P-type semiconductor and the band gap of the N-type semiconductor, wherein
a difference between the band gap of the P-type semiconductor and the band gap of the N-type semiconductor is 1 eV or higher, and
a difference between the band gap of the N-type semiconductor and the band gap of the insulator is 1 eV or lower.

5. The semiconductor diode according to claim 4, wherein
in a state in which positive voltage is applied to the P-type semiconductor from outside of the semiconductor diode by using the N-type semiconductor as a reference,
an energy level of a valence band of the P-type semiconductor is set so as to be lower than an energy level of a valence band of the N-type semiconductor, and
an energy level of a conduction band of the N-type semiconductor is set so as to be lower than an energy level of a conduction band of the P-type semiconductor.

6. The semiconductor diode according to claim 4, wherein
a P-type single-element semiconductor or a P-type zero band-gap semiconductor is used for the P-type semiconductor, and
an oxide semiconductor is used for the N-type semiconductor.

7. The semiconductor diode according to claim 1, wherein
the positive voltage applied from the outside is 1 V or higher.

8. The semiconductor diode according to claim 1, wherein
a surface of the P-type semiconductor or the N-type semiconductor facing the insulator is formed to have a shape with projections and depressions or a porous shape.

9. The semiconductor diode according to claim 1, wherein
a lithium-based perovskite compound such as LiNbO₃, Li₃PS₄, LiBH₄, or the like or a manganese-based perovskite compound such as LaMnO3, etc. is used for the insulator.

10. The semiconductor diode according to claim 2, wherein
an oxide semiconductor is used for the P-type semiconductor, and
an N-type single-element semiconductor or an N-type zero band-gap semiconductor is used for the N-type semiconductor.

11. The semiconductor diode according to claim 5, wherein
a P-type single-element semiconductor or a P-type zero band-gap semiconductor is used for the P-type semiconductor, and
an oxide semiconductor is used for the N-type semiconductor.

12. The semiconductor diode according to claim 11, wherein
the positive voltage applied from the outside is 1 V or higher.

13. The semiconductor diode according to claim 10, wherein
the positive voltage applied from the outside is 1 V or higher.

14. The semiconductor diode according to claim 2, wherein
the positive voltage applied from the outside is 1 V or higher.

15. The semiconductor diode according to claim 3, wherein
the positive voltage applied from the outside is 1 V or higher.

16. The semiconductor diode according to claim 4, wherein
the positive voltage applied from the outside is 1 V or higher.

17. The semiconductor diode according to claim 5, wherein
the positive voltage applied from the outside is 1 V or higher.

18. The semiconductor diode according to claim 6, wherein
the positive voltage applied from the outside is 1 V or higher.

19. The semiconductor diode according to claim 2, wherein
a surface of the P-type semiconductor or the N-type semiconductor facing the insulator is formed to have a shape with projections and depressions or a porous shape.

20. The semiconductor diode according to claim 3, wherein
a surface of the P-type semiconductor or the N-type semiconductor facing the insulator is formed to have a shape with projections and depressions or a porous shape.
